(19) United States
(12) Patent Application Publication
(10) Pub. No.: US 2012/0190151 A1
(43) Pub. Date: Jul. 26, 2012

(54) METHOD FOR THE ACTIVATION OF CdTe THIN FILMS FOR THE APPLICATION IN CdTe/CdS TYPE THIN FILM SOLAR CELLS

(76) Inventors: Nicola Romeo, Parma (IT); Alessandro Romeo, Parma (IT); Alessio Bosio, Parma (IT)

(21) Appl. No.: 13/498,124

(22) PCT Filed: Oct. 11, 2010
(86) PCT No.: PCT/IB2010/054587

§ 371 Date: Apr. 11, 2012

(30) Foreign Application Priority Data
Oct. 13, 2009 (IT) FI2009A000220

(51) Int. Cl. H01L 31/18

(52) U.S. Cl. 438/95; 257/E31.015

(57) ABSTRACT

A method for activation of CdTe films used in CdTe/CdS type thin film solar cells is described, in which a CdTe film is treated with a mixture formed by a fluorine-free chlorinated hydrocarbon and a gaseous chlorine-free fluorinated hydrocarbon. The fluorine-free chlorinated hydrocarbon and the gaseous chlorine-free fluorinated hydrocarbon are harmless to the ozone layer.

### FIELD OF THE INVENTION

The present invention generally relates to the field of the production of thin film solar cells of the CdTe/CdS type and more in particular it refers to a method for the activation of CdTe thin films that are suitable for being applied in this type of solar cells.

### BACKGROUND OF THE INVENTION

It has been demonstrated at a laboratory scale that the thin film solar cells of the CdTe/CdS type can reach efficiencies of 16.5% [X. Wu, Solar Energy 77, 803 (2004)]. However, in order to obtain such a high efficiency, a rather complex method and a rather costly “alkali free” glass substrate were used. According to a simplified method, using cost-effective “soda-lime” glass, it is possible to manufacture thin film solar cells of the CdTe/CdS type with an efficiency of 15.8% [N. Romeo et al., Solar Energy 77, 795 (2004)].

In any case, such high efficiency values are obtained only if the CdTe is treated at a temperature comprised between 380 and 420° C. in a chlorine-containing atmosphere. This treatment, hereafter indicated as activation treatment, on one hand improves the crystalline quality of the CdTe, increasing the dimensions of the crystalline grains and passivating the grain boundaries, and on the other hand it causes a part of the CdS to mix with the CdTe and p-dopes the CdTe by introducing Cd vacancies (V_{Cd}) associated with the Cl which are surface acceptor levels in the CdTe.

In general the activation treatment is carried out through the reaction

CdTe (solid)+2 Cl₂ (gas) TeCl₂(gas)+CdCl₂ (gas)

In this way the smaller grains of CdTe, being bonded more weakly, enter vapour phase and, by resolidifying, increase the dimensions of the bigger grains.

There are different methods for providing the chlorine necessary for the activation treatment of the CdTe film.

The most common method is that of immersing CdTe in a solution that is saturated with CdCl₂ and methanol and letting CdCl₂ deposit over CdTe. After this, the two overlapping layers are put in an oven, brought to a temperature of 380-420° C. and left at this temperature for 10-30 minutes. At the end of this treatment, it is necessary to carry out an etching in Br-methanol or in a mixture of HNO₃-HPO₃ acids to remove the residual CdCl₂ and possible oxides formed on the surface of the CdTe. In addition the etching treatment also has the function of creating a Te-rich surface that is needed to form a good electrical contact on the CdTe [D. Bonnet, Thin Solid Films, 361-362 (2000) 547-552].

Another way is that of depositing the CdCl₂ through vacuum evaporation above the CdTe and carry on the aforementioned method.

Alternatively, the treatment is carried out in an inert gas so as to avoid the formation of oxides on the surface of CdTe [N. Romeo et al., Proc. 21st European Photovoltaic Solar Energy Conference 4-8 Sep. 2006, Dresden, Germany, pp. 1806-1809].

A further method is that of supplying the CI by using aggressive gases of the HCl or Cl₂ type [T. X. Zhou et al., Proc. of the 1st WCPEC (1994), pgs. 103-106]. However, it is preferable to avoid the use of these aggressive gases in an industrial plant as they cause storage and handling problems.

Finally, WO 2006/085348 describes a method that uses non-toxic, Cl-containing inert gases. These gases belong to the Freon family, such as difluorochloromethane (HCF₂Cl). Although these gases are neither toxic nor aggressive, they shall be banned in 2010 because they contribute to the reduction of the ozone layer.

### OBJECTS AND SUMMARY OF THE INVENTION

The purpose of the present invention is to provide a method for the activation of a thin film of CdTe, which can be used in processes for the production of thin film solar cells of the CdTe/CdS type, through the use of inert and non-toxic products and that are harmless to the ozone layer.

Another purpose of the present invention is to provide a method of the above mentioned type in which a sufficient amount of chlorine and fluorine suitable for treating the films of CdTe is provided without directly supplying CdCl₂ or HCl from outside.

These objects are reached with the method for activating the thin film of CdTe in a process for producing thin film solar cells of the CdTe/CdS type in which the film of CdTe is treated with a mixture formed by a fluorine-free chlorinated hydrocarbon and by a chlorine-free fluorinated hydrocarbon.

In particular, as fluorine-free chlorinated hydrocarbons suitable for the purposes of the present invention, those listed in the following table can be used:

TABLE 1
liquid chlorinated hydrocarbons

| Name | Formula |
|---|---|
| Dichloromethane | CH₂Cl₂ |
| Trichloromethane | CHCl₃ |
| Tetrachloromethane | CCl₄ |
| 1,1-dichloroethane | CH₃CHCl₂ |
| 1,2-dichloroethane | ClCH₂CH₂Cl |
| 1-chloropropane | ClCH₂CH₂CH₃ |
| 2-chloropropane | CH₃CH₂ClCH₃ |
| 1,1-dichloropropane | Cl₂CHCH₂CH₃ |
| 1,2-dichloropropane | ClCH₂CHClCH₃ |
| 1,3-dichloropropane | ClCH₂CH₂CH₂Cl |
| 2,2-dichloropropane | CH₃CCl₂CH₃ |
| 1-chlorobutane | ClCH₂CH₂CH₂CH₃ |
| 2-chlorobutane | CH₃CHClCH₂CH₃ |
| 1-chloro,2-methylpropane | ClCH₂CH(CH₃)CH₃ |
| 1,2-dichloro,2-methylpropane | ClCH₂CCl(CH₃)CH₃ |
| 1,2-dichlorobutane | ClCH₂CHClCH₂CH₃ |
| 1,3-dichlorobutane | ClCH₂CH₂CHClCH₃ |
| 1,4-dichlorobutane | ClCH₂CH₂CH₂CH₂Cl |
| 1-chloropentane | ClCH₂CH₂CH₂CH₂CH₃ |
| 1-chloro2-methylbutane | ClCH₂CH₂(CH₃)CH₂CH₃ |
| 1-chloro2,2-dimethylpropane | ClCH₂CH(CH₃)₂CH₃ |
| Trichloro derivatives of higher alkanes | CₙH₂ₙ₋₁Cl₃ |
| chloroethylene | CH₂═CHCl |
| 1,2 dichloroethylene | HClC═CClH |
| 2,2 dichloroethylene | H₂C═CCl₂ |
| 1,2,3 trichloroethylene | HClC═CCl₂ |
| tetrachloroethylene | Cl₂C═CCl₂ |
| 1-chloropropene | ClCH═CHCH₃ |
| 2-chloro,1-propene | CH═CClCH₃ |
| 1,2-dichloropropene | HClC═CClCH₃ |
| Chlorobutene | HClC═CH₂CH₃ |
| Trichloro derivatives of higher alkenes | CₙH₂ₙ₋₃Cl₃ |
| Dichloropropyne | ClC═CCl |

The trichloro derivatives of higher alkanes of interest for the present invention are the hydrocarbon derivatives of the alkanes (CₙH₂ₙ₊₂, with n<17), wherein three hydrogen atoms are replaced with three chlorine atoms (CₙH₂ₙ₋₁Cl₃).

The trichloro derivatives of higher alkenes of interest for the present invention are the hydrocarbon derivatives of the alkenes (CₙH₂ₙ, with n<15) wherein three hydrogen atoms are replaced with three chlorine atoms (CₙH₂ₙ₋₃Cl₃).

For the purposes of the present invention, it is important for the used chlorinated hydrocarbons to have the following properties:

1. a liquefying temperature comprised between 193K (−100° C.) and 318K (25° C.), i.e. they are liquids at room temperature,

2. a vapour pressure comprised between 10⁻⁶ Pa (10⁻¹ mbar) and 10⁵ Pa (1 atm) at the temperature of 293K

3. a dissociation temperature comprised between 393K (100° C.) and 843K (550° C.).

Amongst these, the preferred chlorinated hydrocarbons are: 1-chlorobutane (CH₃(CH₂)₃Cl), 1,1,2-trichloroethylene (CHClCCl₂), and dichloromethane (CH₂Cl₂).

The chlorine-free fluorinated hydrocarbons (hydrofluorocarbons) suitable for the purposes of the present invention can be selected from those listed in the following table:

TABLE 2
Hydrofluorocarbons

| | | Chemical |
|---|---|---|
| Trade name | Name | formula |
| HFC-23 | trifluoromethane | CHF₃ |
| HFC-32 | difluoromethane | CH₂F₂ |
| HFC-125 | Pentafluoroethane | CHF₂CF₃ |
| HFC-134a | 1,1,1,2-tetrafluoroethane | CH₂FCF₃ |
| HFC-143a | 1,1,1-trifluoroethane | CH₃CF₃ |
| HFC-152a | 1,1-difluoroethane | CH₃CHF₂ |
| HFC-227ea | 1,1,1,2,3,3,3-heptafluoroethane | CF₃CHFCF₃ |
| HFC-236fa | 1,1,1,3,3,3-hexafluoropropane | CF₃CH₂CF₃ |
| HFC-245fa | 1,1,1,3,3-pentafluoropropane | CHF₂CH₂CF₃ |
| HFC-365-mfc | 1,1,1,3,3-pentafluorobutane | CH₃CF₂CH₂CF₃ |
| HFC-43-10mee | 1,1,1,2,3,4,4,5,5,5- | CF₃CHFCHFCF₂CF₃ |
| | decafluoropentane | |

Amongst these, the preferred fluorinated hydrocarbons are trifluoromethane (CHF₃), R-134a (1,1,1,2-tetrafluoroethane, CH₂FCF₃) and R-152a (1,1-difluoroethane, CH₃CHF₂)

By mixing a compound of the family of the chlorinated hydrocarbons (table 1) with a gas of the family of the fluorinated hydrocarbons (table 2) and treating the film of CdTe with the mixture thus obtained, results are obtained similar to those obtained with difluorochloromethane as described in WO 2006/085348.

The morphology of the CdTe after the treatment with the aforementioned mixture is very similar to that obtained with CHF₂Cl. Moreover, the formation of micro-particles of carbon on the surface of the CdTe, that form by using the sole chlorinated compound, is inhibited probably because the fluorine-containing gas tends to bond the carbon.

Another role of the fluorinated hydrocarbon could be that of forming the (V_{Cd}-F) group that gives a surface level in the CdTe and that could be more effective than the (VCd—Cl) group in p-doping the CdTe.

The best results have been obtained by using 1-chlorobutane mixed with R-134a (C₂H₂F₄) or R-152a (F₂HC—CH₃) with the proportion 2 mbar of 1-chlorobutane/200 mbar of R-134a or R-152a.

The treatment conditions are as follows:

Treatment conditions

| | | | | |
|---|---|---|---|---|
| | Chlorinated | Fluorinated | | |
| | hydrocarbon | hydrocarbon + | | |
| Treatment | partial | Ar | Treatment | Efficiency of |
| Temperature | pressure | Partial pressure | duration | the device |
| [° C.] | [mbar] | [mbar] | [min] | [%] |

Example 1
dichloromethane (CH₂Cl₂) + Tetrafluoroethylene(C₂H₂F₄)

| | | | | |
|---|---|---|---|---|
| 400 | 1 | 500 | 15 | 13.3 |
| | 5 | 500 | 10 | 12.0 |

Example 2
1-chlorobutane (CH₃(CH₂)₃Cl) + Tetrafluoroethylene (C₂H₂F₄)

| | | | | |
|---|---|---|---|---|
| 400 | 2 | 200 | 15 | 15.1 |
| | | (P_{Ar} = 0) | | |
| | 5 | 200 | 10 | 10.6 |
| | | (P_{Ar} = 0) | | |

Example 3
trichloroethylene (C₂HCl₃) + Tetrafluoroethylene (C₂H₂F₄)

| | | | | |
|---|---|---|---|---|
| 400 | 5 | 500 | 15 | 10.0 |
| | 10 | 500 | 10 | 8.4 |

Example 4
1-chlorobutane (CH₃(CH₂)₃Cl) + 1,1-difluoroethane (F₂HC—CH₃)

| | | | | |
|---|---|---|---|---|
| 400 | 2 | 200 | 15 | 15.4 |
| | | (P_{Ar} = 0) | | |
| | 5 | 200 | 10 | 14.8 |
| | | (P_{Ar} = 0) | | |

The sample used is a soda-lime glass covered in sequence by 0.5 μm of ITO, 0.1 μm of ZnO, 0.1 μm of CdS and 6 μm of CdTe, as in the prior art. The experiments were carried out by using a quartz ampoule in which the sample is introduced and that is evacuated through a rotary turbomolecular pump system reaching a vacuum of at least 10⁻⁴-10⁻³ Pa (10⁻⁶-10⁻⁵ mbar). The ampoule is brought to a temperature that varies from 350 to 400° C. A controlled amount of chlorinated hydrocarbon is introduced into the ampoule, said amount being measured through a “baratron” type measuring head. The pressure of the chlorinated hydrocarbon is adjusted between 50 and 2000 Pa (5×10⁻¹ and 20 mbar). The fluorinated hydrocarbon with partial pressure that are from 1×10⁴ to 5×10⁴ Pa (100 to 500 mbar) is also added. An inert gas can be added to this mixture of hydrocarbons, such as Ar, with partial pressure ranging from 10⁴ to 0 Pa (100 to 0 mbar), so as to reach a total pressure of 5×10⁴ Pa (500 mbar).

The cells are completed by making the back-contact on the activated CdTe film according to the method of the invention. The efficiency of the cells produced in this way resulted comparable to that of the cells obtained by using CHF₂Cl, i.e. comprised between 14 and 15.4%.

1. A method for activation of CdTe films used in CdTe/CdS type thin film solar cells, the method comprising treating a CdTe film with a mixture comprising a fluorine-free chlorinated hydrocarbon and a gaseous chlorine-free hydrofluorocarbon, wherein the fluorine-free chlorinated hydrocarbon and the gaseous chlorine-free hydrofluorocarbon are harmless to the ozone layer.

2. The method according to claim 1, wherein the fluorine-free chlorinated hydrocarbon is selected from the group consisting of the following compounds:

| Compound name | Compound Formula |
|---|---|
| Dichloromethane | CH₂Cl₂ |
| Trichloromethane | CHCl₃ |
| Tetrachloromethane | CCl₄ |
| 1,1-dichloroethane | CH₃CHCl₂ |
| 1,2-dichloroethane | ClCH₂CH₂Cl |
| 1-chloropropane | ClCH₂CH₂CH₃ |
| 2-chloropropane | CH₃CH₂ClCH₃ |
| 1,1-dichloropropane | Cl₂CHCH₂CH₃ |
| 1,2-dichloropropane | ClCH₂CHClCH₃ |
| 1,3-dichloropropane | ClCH₂CH₂CH₂Cl |
| 2,2-dichloropropane | CH₃CCl₂CH₃ |
| 1-chlorobutane | ClCH₂CH₂CH₂CH₃ |
| 2-chlorobutane | CH₃CHClCH₂CH₃ |
| 1-chloro,2-methylpropane | ClCH₂CH(CH₃)CH₃ |
| 1,2-dichloro,2-methylpropane | ClCH₂CCl(CH₃)CH₃ |
| 1,2-dichlorobutane | ClCH₂CHClCH₂CH₃ |
| 1,3-dichlorobutane | ClCH₂CH₂CHClCH₃ |
| 1,4-dichlorobutane | ClCH₂CH₂CH₂CH₂Cl |
| 1-chloropentane | ClCH₂CH₂CH₂CH₂CH₃ |
| 1-chloro2-methylbutane | ClCH₂CH₂(CH₃)CH₂CH₃ |
| 1-chloro2,2-dimethylpropane | ClCH₂CH(CH₃)₂CH₃ |
| Trichloro derivatives of higher alkanes | CₙH₂ₙ₋₁Cl₃ |
| chloroethylene | CH₂═CHCl |
| 1,2 dichloroethylene | HClC═CClH |
| 2,2 dichloroethylene | H₂C═CCl₂ |
| 1,2,3 trichloroethylene | HClC═CCl₂ |
| tetrachloroethylene | Cl₂C═CCl₂ |
| 1-chloropropene | ClCH═CHCH₃ |
| 2-chloro,1-propene | CH═CClCH₃ |
| 1,2-dichloropropene | HClC═CClCH₃ |
| Chlorobutene | HClC═CH₂CH₃ |
| Trichloro derivatives of higher alkenes | CₙH₂ₙ₋₃Cl₃ |
| Dichloropropyne | ClC═CCl. |

3. The method according to claim 1, wherein the fluorine-free chlorinated hydrocarbon has a formula CₙH₂ₙ₊₂₋ₘClₘ, wherein n is less than 17 and m is between 1 and 4.

4. The method according to claim 1, wherein the chlorinated hydrocarbon is selected from the group consisting of 1-chlorobutane, 1,1,2-trichloroethylene and dichloromethane.

5. The method according to claim 1, wherein the gaseous chlorine-free hydrofluorocarbon is selected from the group consisting of the following compounds:

| Compound name | Compound Formula |
|---|---|
| trifluoromethane | CHF₃ |
| difluoromethane | CH₂F₂ |
| Pentafluoroethane | CHF₂CF₃ |
| 1,1,1,2-tetrafluoroethane | CH₂FCF₃ |
| 1,1,1-trifluoroethane | CH₃CF₃ |
| 1,1-difluoroethane | CH₃CHF₂ |
| 1,1,1,2,3,3,3-heptafluoroethane | CF₃CHFCF₃ |
| 1,1,1,3,3,3-hexafluoropropane | CF₃CH₂CF₃ |
| 1,1,1,3,3-pentafluoropropane | CHF₂CH₂CF₃ |
| 1,1,1,3,3-pentafluorobutane | CH₃CF₂CH₂CF₃ |
| 1,1,1,2,3,4,4,5,5,5-decafluoropentane | CF₃CHFCHFCF₂CF₃. |

6. The method according to claim 5, wherein the gaseous chlorine-free hydrofluorocarbon is selected form the group consisting of trifluoromethane, tetrafluoroethane and 1,1-difluoroethane.

7. The method according to claim 1, wherein the fluorine-free chlorinated hydrocarbon and the gaseous chlorine-free hydrofluorocarbon in the mixture have the following partial pressure ranges:
fluorine-free chlorinated hydrocarbon: 50-2000 Pa;
gaseous chlorine-free hydrofluorocarbon: 1×10⁴−5×10⁴ Pa.

8. The method according to claim 7, wherein a partial pressure ratio of fluorine-free chlorinated hydrocarbon to gaseous chlorine-free hydrofluorocarbon is 200 Pa/2×10⁴ Pa, when the chlorinated hydrocarbon is 1-chlorobutane and the hydrofluorocarbon is 1,1-difluoroethane.

9. The method according to claim 1, wherein the the treating of the CdTe film is conducted at a temperature comprised between 350 and 450° C.

10. The method according to claim 1, wherein the mixture further comprises an inert gas to the mixture, wherein the partial pressure of the inert gas is in a range of 10⁴ and 0 Pa (100 and 0 mbar), to provide a total mixture pressure of 5×10⁴ Pa (500 mbar).

11. The method according to claim 1, wherein the fluorine-free chlorinated hydrocarbon has a formula CₙH₂ₙ₋ₘClₘ, wherein n is less than 15 and m is between 1 and 4.
